(19) United States
(12) Patent Application Publication
(10) Pub. No.: US 2026/0212941 A1
(43) Pub. Date: Jul. 23, 2026

(54) READ-WRITE TESTING METHOD, DEVICE, AND STORAGE MEDIUM FOR MEMORY STORAGE DEVICE

(71) Applicant: Shenzhen Rayson Technology Co., Ltd., Shenzhen (CN)

(72) Inventor: Zufang Yang, Shenzhen (CN)

(21) Appl. No.: 19/403,890

(22) Filed: Nov. 30, 2025

(30) Foreign Application Priority Data
Jan. 23, 2025 (CN) 2025101058563

(51) Int. Cl. G11C 29/12; G11C 29/14; G11C 29/36

(52) U.S. Cl. CPC G11C 29/1201; G11C 29/14; G11C 29/36

(57) ABSTRACT

The disclosure provides a read-write testing method, a device, and storage medium for a memory storage device, belonging to the field of memory technology. The method comprises obtaining the number of data blocks of a target memory storage device to be tested and the number of rows in each of the data blocks; determining the number of test threads to be created based on the number of data blocks, the number of rows, and the read-write type; creating the number of test threads and determining the read-write starting positions for each of the test threads from the row regions of each of the data blocks; synchronously invoking each of the created test threads and outputting the test results, so as to perform synchronous read-write testing from the corresponding read-write starting positions through each test thread. The embodiments of this application can improve testing efficiency.

### TECHNICAL FIELD

This application relates to the field of memory technology, particularly to a read-write testing method, a device, and storage medium for a memory storage device.

### BACKGROUND

Memory storage devices (such as DDR), as a common type of memory, often require coverage testing of the data at each bit position within the memory storage device during read-write testing. However, as the storage capacity of memory storage devices increases, the testing duration for each memory storage device also lengthens. Moreover, with an increase in the number of memory storage devices, the total testing duration further extends. Therefore, in related technologies, there is an urgent need for a read-write testing method for memory storage devices that can optimize the testing duration.

### SUMMARY

The main objective of the embodiments of this application is to propose a read-write testing method, a device, and storage medium for memory storage devices that can enhance testing efficiency.

In order to achieve this objective, the first aspect of the embodiments of this application proposes a read-write testing method for memory storage devices, the method comprising:

acquiring the number of data blocks and the number of rows in each data block of a target memory storage device to be tested;

determining the number of test threads to be created based on the number of data blocks, the number of rows, and the read-write type;

creating the number of test threads and determining the read-write starting positions for each test thread from the row regions of each data block;

synchronously invoking each created test thread and outputting test results, so as to perform synchronous read-write testing from the corresponding read-write starting positions through each test thread.

In order to achieve the aforementioned objective, the second aspect of the embodiments of this application proposes an electronic device, the electronic device comprising a memory and a processor, wherein the memory stores a computer program, and the processor implements the read-write testing method for memory storage devices described in any item of the first aspect when executing the computer program.

In order to achieve the aforementioned objective, the third aspect of the embodiments of this application proposes a computer-readable storage medium, the storage medium storing a computer program that implements the read-write testing method for memory storage devices described in any item of the first aspect when executed by a processor.

The read-write testing method, a device, and storage medium for memory storage devices proposed in this application configure multiple test threads for a single memory storage device, with each test thread capable of testing at least one row region. This enables faster feedback of test results for different storage locations of a single memory storage device when synchronously invoking multiple test threads for testing the same memory storage device. Consequently, the probability of early detection of fault points in the memory storage device increases, thereby enhancing testing efficiency. As the testing efficiency for a single memory storage device is improved, the overall testing efficiency is also enhanced when testing multiple memory storage devices. Furthermore, compared to providing a testing environment for each memory storage device, the testing cost is lower. Therefore, the embodiments of this application offer higher testing efficiency and lower testing costs.

### BRIEF DESCRIPTION OF THE DRAWINGS

FIG. 1 is a schematic flow diagram of the read-write testing method for memory storage devices provided in this application;

FIG. 2 is a schematic structural diagram of a memory storage device in an embodiment of the read-write testing method for memory storage devices provided in this application;

FIG. 3 is a schematic diagram illustrating the allocation of test threads in a memory storage device in an embodiment of the read-write testing method for memory storage devices provided in this application;

FIG. 4 is a schematic diagram illustrating the allocation of test threads in a memory storage device in another embodiment of the read-write testing method for memory storage devices provided in this application;

FIG. 5 is a schematic diagram illustrating the allocation of test threads in a memory storage device in yet another embodiment of the read-write testing method for memory storage devices provided in this application;

FIG. 6 is a schematic structural diagram of the corresponding hardware architecture for the read-write testing method for memory storage devices provided in this application.

### DETAILED DESCRIPTION

In order to make the objectives, technical solutions, and advantages of this application clearer and more comprehensible, further detailed descriptions are provided below in conjunction with the accompanying drawings and embodiments. It should be understood that the specific embodiments described herein are merely intended to explain this application and are not intended to limit its scope.

It should be noted that although functional modules are divided in the device schematic diagrams and logical sequences are shown in the flowcharts, in certain cases, the steps illustrated or described may be executed in a different order than the module divisions in the device or the sequences in the flowcharts. The terms "first," "second," etc., used in the specification, claims, and the aforementioned drawings are intended to distinguish similar objects and are not necessarily used to describe a specific order or sequence.

Unless otherwise defined, all technical and scientific terms used herein have the same meanings as commonly understood by technicians in the technical field to which this application belongs. The terms used herein are solely for the purpose of describing the embodiments of this application and are not intended to limit its scope.

First, let's clarify several terms involved in this application:

DDR, also known as Double Data Rate Synchronous Dynamic Random Access Memory (DDR SDRAM).

As a common type of memory, memory storage devices (such as DDR) often require coverage testing of the data at each bit position during read-write testing. However, as the storage capacity of memory storage devices increases, the number of data blocks contained in each memory storage device and the capacity of each data block will correspondingly increase. At this point, to ensure coverage of each bit position in every data block, the testing duration for a single memory storage device will lengthen. Moreover, with an increase in the number of memory storage devices, the total testing duration for all memory storage devices will further extend. Therefore, in related technologies, there is an urgent need for a read-write testing method for memory storage devices that can optimize the testing duration. Based on this, the embodiments of this application provide a read-write testing method, the device, and storage medium for memory storage devices that can enhance testing efficiency.

The read-write testing method, the device, and storage medium for memory storage devices provided in the embodiments of this application are specifically described through the following embodiments. First, the read-write testing method for memory storage devices in the embodiments of this application is described.

The read-write testing method for memory storage devices in this application can be applied to various general-purpose or specialized computer system environments or configurations, such as personal computers, server computers, handheld or portable devices, tablet devices, multiprocessor systems, and so on. This application can be described in the general context of computer-executable instructions executed by a computer, such as program modules. Generally, program modules comprise routines, programs, objects, components, data structures, etc., that perform specific tasks or implement specific abstract data types. This application can also be practiced in distributed computing environments, where tasks are executed by remote processing devices connected through a communication network. In distributed computing environments, program modules can be located in both local and remote computer storage media, such as storage devices.

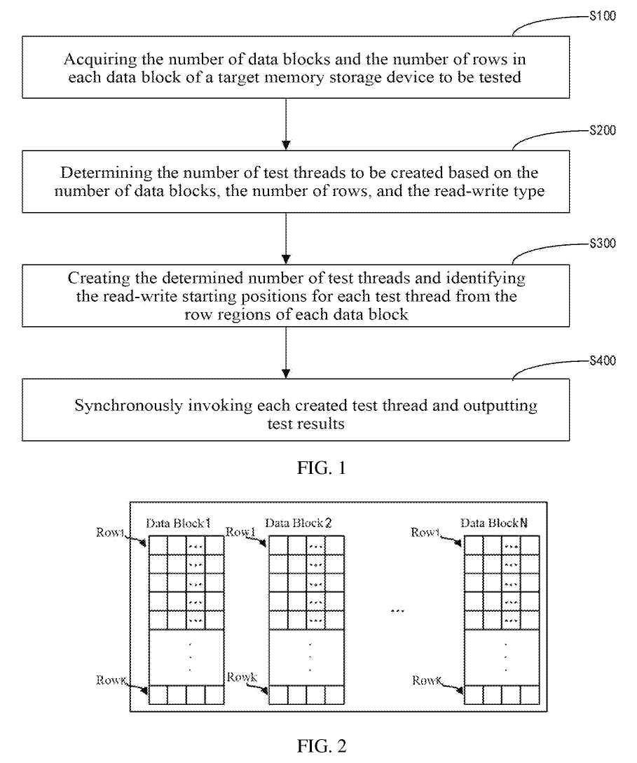

It can be understood that, with reference to FIG. 1, according to a read-write testing method for memory storage devices provided in an embodiment of this application, the method comprises:

Step S100: acquiring the number of data blocks and the number of rows in each data block of a target memory storage device to be tested;

Step S200: determining the number of test threads to be created based on the number of data blocks, the number of rows, and the read-write type;

Step S300: creating the determined number of test threads and identifying the read-write starting positions for each test thread from the row regions of each data block;

Step S400: synchronously invoking each created test thread and output test results, so as to perform synchronous read-write testing from the corresponding read-write starting positions through each test thread.

Therefore, by configuring multiple test threads for a single memory storage device, with each test thread capable of testing the row region of at least one row, the feedback of test results for different storage locations of a single memory storage device can be accelerated when synchronously invoking multiple test threads for testing the same memory storage device. This increases the likelihood of early detection of fault points in the memory storage device, thereby enhancing testing efficiency. As the testing efficiency for a single memory storage device is improved, the overall testing efficiency is also enhanced when testing multiple memory storage devices. Furthermore, compared to providing a testing environment for each memory storage device, the testing cost is lower. Therefore, the embodiments of this application offer higher testing efficiency and lower testing costs.

The read-write testing method for memory storage devices in this application is applied to a testing platform. Technicians in the field can select devices capable of supporting multiple test threads for testing based on actual testing requirements. For example, the testing platform is connected to the memory storage device via an SOC (System on a Chip) interface. The testing platform creates nine test threads, which synchronously invoke the SOC interface to initiate read-write tests on different addresses of the target memory storage device.

It can be understood that for a target memory storage device, each target memory storage device can be divided into multiple data blocks of the same size, with each data block further divided into multiple row regions. Each row region contains the same number of bit positions and can store the same amount of data. For instance, as shown in FIG. 2, a DDR is divided into N data blocks, labeled as Data Block 1 to Data Block N. Each data block is further divided into K row regions, labeled as Row 1 to Row K. Each row region consists of M bit positions, with each bit position corresponding to a storage address for storing one bit of data.

The read-write type refers to the manner in which the CPU reads from or writes to the data blocks of the memory storage device in practical applications. The read-write types comprise sequential read-write of individual data blocks and synchronous read-write of multiple data blocks. Different read-write types determine the mapping relationship between test threads and data blocks/row regions within data blocks, as well as the execution order of data blocks and row regions. For example, in the sequential read-write mode of individual data blocks, each data block is executed sequentially, with test threads mapping to the row regions of the currently tested data block. In the synchronous read-write mode of multiple data blocks, execution proceeds according to the row region numbering, with the data blocks of the tested row regions mapping to the test threads. One or more of the aforementioned read-write types can be selected for testing based on actual requirements, and technicians in the field can set them selectively according to their needs.

The read-write starting position represents the storage address where each test thread begins its read or write operation. During actual testing, the read-write starting position can be randomly set or fixed based on the requirement for continuous coverage of test data. This ensures that when multiple threads write simultaneously, starting from the read-write starting position, the data blocks where the starting read-write position is located are continuously written with data, and the coverage of addresses in the memory storage device meets the requirements. Technicians in the field can set the read-write starting position selectively according to actual needs and construct test data based on the read-write starting position to meet the aforementioned testing requirements.

The read-write test comprises at least one of read testing or write testing, and technicians in the field can set it selectively according to actual needs.

This application does not impose restrictions on how the test results are presented. Technicians in the field can set them selectively according to their requirements.

This application does not impose restrictions on how to obtain the number of data blocks and the number of rows in Step S100. Technicians in the field can set it selectively according to actual needs. For example, by setting up a visual view, testers can select the memory type of the target memory storage device to be tested in the visual view. Based on a mapping table in a pre-configured file that associates each memory type with the number of data blocks and the number of rows, the number of data blocks and the number of rows for the target memory storage device can be determined by looking up the table.

The number of threads is a positive integer greater than 1. This application does not impose restrictions on how to determine the number of threads, and technicians in the field can set it selectively according to actual needs.

It can be understood that there are multiple read-write types set, including sequential read-write per data block and synchronous read-write across multiple data blocks. Determining the number of test threads to be created based on the number of data blocks, the number of rows, and the read-write type, comprises:

determining the first number of threads corresponding to sequential read-write per data block based on the number of rows, wherein each test thread corresponds to at least one row region;

determining the second number of threads corresponding to synchronous read-write across multiple data blocks based on the number of data blocks;

determining the total number of threads based on the first and second numbers of threads.

Sequential read-write per data block means that during the process of writing data to the memory storage device, when one data block cannot accommodate further data and there is still data to be written, data is written to a data block with available space. Synchronous read-write across multiple data blocks means that data blocks for writing can be arbitrarily selected based on the size of the data to be written, and the data to be written is dispersed and synchronously written to the selected multiple data blocks. There are no restrictions on the number of data blocks to be written. For example, if the total amount of data to be written requires the capacity of multiple data blocks, in the sequential read-write per data block mode, after selecting one data block, data is first written to that data block until it cannot accommodate further data, and then a new data block with available space is selected to write the remaining data. In the synchronous read-write across multiple data blocks mode, multiple data blocks can be selected simultaneously, and write operations can be performed on these multiple data blocks concurrently.

Determining the number of threads separately for sequential read-write per data block and synchronous read-write across multiple data blocks can enhance testing efficiency when conducting use case tests under two different read-write type scenarios.

It can be understood that the larger of the first and second thread counts can be used as the initially created thread count. In other embodiments, a smaller number of threads can be initially created, and if further testing is required after completion, the thread count can be increased to meet the testing requirements for the specific scenario type.

This application does not impose restrictions on how to determine the first thread count based on the number of rows. Each row can correspond to one test thread, or multiple row regions can correspond to one test thread. Similarly, there are no restrictions on how to determine the second thread count based on the number of data blocks.

It can be understood that the number of test threads and the read-write starting positions define the regions of the target memory storage device that each test thread can read from or write to. That is, while determining the thread count, the thread mapping relationship between each test thread and the data blocks/row regions can also be simultaneously determined. The thread mapping relationship varies under different read-write types. Additionally, based on the thread mapping relationship, test data for each test thread can be constructed, enabling automatic testing of the target memory storage device when synchronously invoking each created test thread.

It can be understood that determining the second thread count corresponding to synchronous read-write across multiple data blocks based on the number of data blocks, comprises:

obtaining the maximum number of writable threads that can be created;

dividing the maximum number of writable threads by the number of data blocks and rounding down the result to determine the first thread multiplier if the maximum number of writable threads is greater than or equal to the number of data blocks;

determining the number of writable threads per data block based on the first thread multiplier;

determining the target number of writable threads based on the number of writable threads per data block and the number of data blocks;

determining the second thread count corresponding to synchronous read-write across multiple data blocks based on the target number of writable threads.

The maximum number of writable threads represents the number of threads allowed to be created for write testing. In some embodiments, threads are divided into three independent types based on function: read, write, and compare, to test the target memory storage device. In this case, the maximum number of writable threads is one-third of the maximum number of threads supported by the testing platform. For example, if the testing platform supports a maximum of 9 threads, the maximum number of writable threads is 3. It can be understood that in some embodiments, each thread is defined to simultaneously possess read, write, and compare functions, in which case the maximum number of writable threads is the maximum number of threads supported by the testing platform.

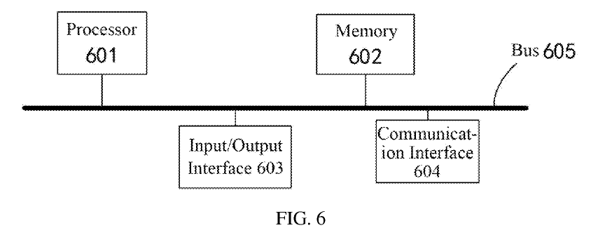

When the maximum number of writable threads is greater than or equal to the number of data blocks, one test thread can be assigned to each data block. The number of threads per data block can be selectively set according to actual needs. As illustrated in FIG. 4, if the target memory storage device is configured with N data blocks, the corresponding target number of writable threads is N. When each test thread possesses read, write, and compare functions simultaneously, the total number of threads equals the target number of writable threads. When test threads are divided based on read, write, and compare functions, the total number of threads is the target number of writable threads multiplied by 3. In other embodiments, as shown in FIG. 5, multiple test threads can also be assigned to each data block. Specifically, as depicted in FIG. 5, each data block is configured with j test threads, labeled as Thread 1 to Thread j.

In this scenario, configuring multiple test threads allows for the early detection of abnormalities during write operations at different memory addresses, thereby facilitating the prompt identification of fault points in the target memory storage device.

For example, if the maximum number of writable threads is set to 10, the number of data blocks is set to 3, and the number of rows in each data block's row region is set to 7, the first thread multiplier can be determined to be 3. That is, up to 3 test threads can be assigned to a single data block. This application does not impose restrictions on how to determine the number of writable threads per data block based on the first thread multiplier; technicians in the field can set it selectively according to actual needs. For instance, a configuration view can be provided for the user to determine the setting, or it can be set based on test feedback efficiency.

It can be understood that determining the second thread count corresponding to synchronous read-write across multiple data blocks based on the number of data blocks also comprises:

dividing the number of data blocks by the maximum number of writable threads and rounding up the result to determine the second thread multiplier when the maximum number of writable threads is less than the number of data blocks ;

determining the second thread count corresponding to synchronous read-write across multiple data blocks based on the second thread multiplier.

For example, if the number of data blocks is 7 and the maximum number of writable threads is 3, rounding up the result of 7 divided by 3 yields a second thread multiplier of 3. This means that, starting from the first data block, a test thread is assigned every 3 data blocks. Specifically, data blocks 1 to 3 correspond to one test thread, data blocks 4 to 6correspond to another test thread, and data block 7 corresponds to a third test thread.

It can be understood that determining the read-write starting positions for each test thread within the row regions of respective data blocks comprises:

acquiring the second thread mapping relationship corresponding to the second thread count under synchronous read-write across multiple data blocks;

determining the starting data block for each test thread under synchronous read-write across multiple data blocks based on the second thread mapping relationship;

randomly generating a second starting row number for each starting data block; and

randomly generating a read-write starting position within the corresponding row region for each second starting row number.

By randomly generating the second starting row number, testing can be conducted at random positions within the same data block, further ensuring the accuracy of the test.

The second thread mapping relationship represents the range of data blocks and row regions that each test thread can read from or write to. The starting data block can be determined randomly or sequentially, such as by recording the number of the last tested data block and, when testing the same target memory storage device again, starting the test from the data block corresponding to the next number.

This application does not impose restrictions on how to randomly determine the second starting row number; technicians in the field can set it based on the mechanism of random functions. In some embodiments, the range for randomly selecting the second starting row number can be determined based on the second thread mapping relationship, ensuring that the second starting row numbers for test threads in different data blocks are all different when data is written based on the randomly generated second starting row numbers.

Furthermore, the address range for generating read-write starting positions within the row region can be further limited based on the second thread mapping relationship, ensuring that the data length written based on the read-write starting positions meets the preset minimum length requirement.

It can be understood that determining the first thread count corresponding to sequential read-write per data block based on the number of rows comprises:

acquiring the maximum number of writable threads that can be created;

dividing the number of rows by the maximum number of writable threads and rounding up the result to determine the third thread multiplier; and

determining the first thread count corresponding to sequential read-write per data block based on the third thread multiplier.

The third thread multiplier ensures that the row region of every row in each data block is covered by the test.

For example, if the number of rows in a single data block is j and the maximum number of writable threads is u, the third thread multiplier is the result of rounding up j divided by u. In this case, each test thread is mapped to the row region of at least one row.

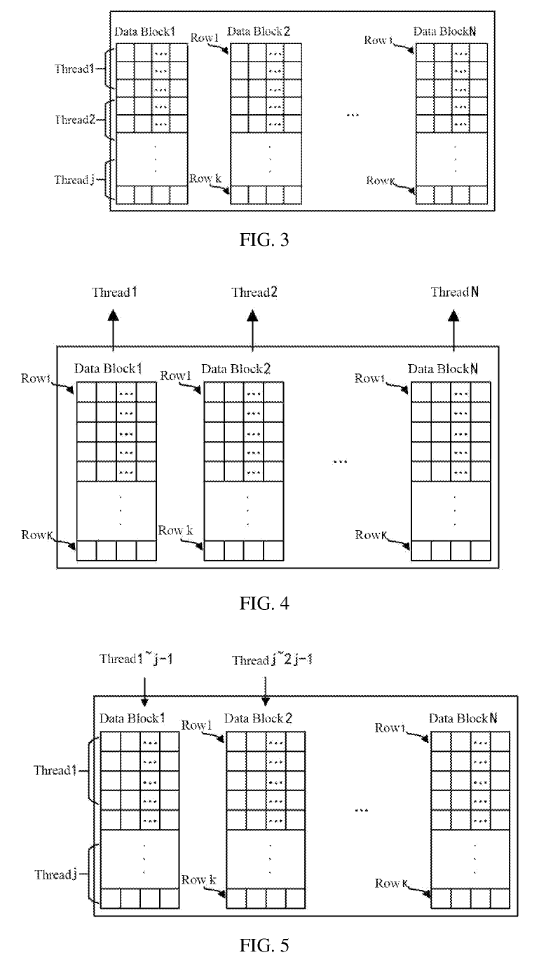

For example, referring to FIG. 3, when the maximum number of writable threads is less than the number of rows in the data blocks (i.e., the third thread multiplier is an integer greater than 1), multiple row regions correspond to one test thread. In other embodiments, when the third multiplier is an integer equal to 1, each row region can correspond to one test thread.

It can be understood that determining the read-write starting positions for each test thread within the row regions of respective data blocks comprises:

identifying target data blocks from among the various data blocks;

acquiring the first thread mapping relationship corresponding to the first thread count;

determining the second starting row numbers for each test thread associated with sequential read-write per data block within the target data blocks based on the first thread mapping relationship;

and randomly generating read-write starting positions within the row regions corresponding to the second starting row numbers for each test thread.

The target data blocks can be randomly selected or chosen based on the length of the test data to ensure that the data blocks can accommodate the length of the test data to be written.

The first thread mapping relationship is determined when the first thread count is established and records the mapping relationships between test threads and data blocks, as well as between test threads and row regions, under sequential read-write per data block.

The second starting row number represents the row number of the row region where the corresponding test thread begins writing test data. In some embodiments, when the number of test threads exceeds the number of rows, each test thread corresponds to a single row region within a data block, and the second starting row number is the row number of the row region corresponding to each test thread. In other embodiments, when the number of test threads is less than the number of rows, one test thread corresponds to multiple row regions, and the starting write position for each test thread can be the row number of any row within the corresponding row regions. This application does not impose restrictions on how to determine the second starting row number when multiple rows are involved; technicians in the field can set it selectively based on actual circumstances.

It can be understood that the test threads comprise read threads, write threads, and compare threads: the read threads, write threads, and compare threads are set up in a one-to-one correspondence. Each created test thread is synchronously invoked, and the test results are output, which comprises:

invoking each write thread to start writing operations from the corresponding read-write starting positions;

invoking each read thread to start reading operations from the read-write starting positions after the data at each read-write starting position has been written;

invoking the compare threads to compare the operational data of the corresponding write threads and read threads and output the comparison results.

By dividing the test threads into three categories, comparisons can be made synchronously after each bit of data is written, enabling the timely detection of fault locations and thereby improving test efficiency.

It can be understood that after the read-write starting positions for the test threads and the target memory storage device have been determined, technicians in the field can construct test data of the same length based on actual circumstances. At this point, result verification can be performed based on the test data and the data read from the target memory storage device.

Since this application performs read, write, and compare operations on individual bits through threads, it can further detect write abnormalities during the writing process or the read-write process.

For illustrative purposes, the read-write testing method for memory storage devices in the embodiments of this application is described with reference to FIGS. 2 to 5, with the specific steps outlined as follows:

S1. displaying a test view in response to a test initiation request; wherein the test view displays a dropdown box for test types of the memory storage device, a selection box for read-write types, and thread types;

S2. determining the target test type, target read-write type, and target thread type from the interaction request in response to an interaction request;

S3. determining the number of data blocks and the number of rows in the target memory storage device based on the target test type;

S4. determine the number of threads based on the number of data blocks, the number of rows, the thread type, and the target read-write type, as detailed below.

When the thread type indicates that a single test thread simultaneously possesses read, write, and compare functions:

setting the maximum number of threads supported by the test platform as the maximum number of writable threads;

determining the first thread count and the first thread mapping relationship by referring to the method for determining thread count for sequential read-write per data block described above, when the target read-write type is set to one and is sequential read-write per data block;

determining the second thread count and the second thread mapping relationship by referring to the method for determining thread count for simultaneous read-write across multiple data blocks described above, when the target read-write type is set to one and is simultaneous read-write across multiple data blocks;

separately determining the first thread count and the first thread mapping relationship for sequential read-write per data block, as well as the second thread count and the second thread mapping relationship for simultaneous read-write across multiple data blocks, when multiple target read-write types are set, including sequential read-write per data block and simultaneous read-write across multiple data blocks.

When the thread type indicates that a single test thread possesses only one of the read, write, or compare functions:

setting the result of dividing the maximum number of threads supported by the test platform by 3 as the maximum number of writable threads;

determining the first thread count and the first thread mapping relationship by referring to the method for determining thread count for sequential read-write per data block described above, when the target read-write type is set to one and is sequential read-write per data block;

determining the second thread count and the second thread mapping relationship by referring to the method for determining thread count for simultaneous read-write across multiple data blocks described above, when the target read-write type is set to one and is simultaneous read-write across multiple data blocks;

separately determining the thread count and thread mapping relationship for sequential read-write per data block, as well as the thread count and thread mapping relationship for simultaneous read-write across multiple data blocks, when multiple target read-write types are set, including sequential read-write per data block and simultaneous read-write across multiple data blocks. In this case, the number of test threads to be created can be set to the maximum of the first thread count and the second thread count.

S4. Based on the number of threads, test threads are created; and the read-write starting positions for each test thread from the row regions of respective data blocks according to the thread mapping relationship are determined.

S5. Based on each read-write starting position, the test data for the target test cases is constructed and displayed.

S6. Each created test thread is invoked synchronously, the test results are output, the test results are comprared with the test data, whether each target test case has been successfully executed is determined, and, if execution fails, the failed memory addresses are displayed.

The embodiments of this application also provide an electronic device. The electronic device comprises a memory and a processor. The memory stores computer programs, and when the processor executes the computer programs, it implements the aforementioned read-write testing method for memory storage devices. This electronic device can be any intelligent terminal, including but not limited to tablet computers and in-vehicle computers.

Please refer to FIG. 6, which illustrates the hardware structure of an electronic device in another embodiment. The electronic device comprises:

a processor 601, which can be implemented using a general-purpose CPU (Central Processing Unit), a microprocessor, an Application-Specific Integrated Circuit (ASIC), or one or more integrated circuits; wherein the processor 601 is configured to execute relevant programs to implement the technical solutions provided by the embodiments of this application;

a memory 602, which can be a NAND flash, wherein relevant program codes are stored in the memory 602, and the processor 601 invokes and executes these codes to implement the read-write testing method for memory storage devices as described in the embodiments of this application;

an input/output interface 603, which is configured to achieve information input and output;

a communication interface 604, which is configured to enable communication interactions between this device and other devices; wherein communication can be achieved through wired means (e.g., USB, network cables, etc.) or wireless means (e.g., mobile networks, Wi-Fi, Bluetooth, etc.);

a bus 605, which transmits information among various components of the device (e.g., processor 601, memory 602, input/output interface 603, and communication interface 604).

The processor 601, the memory 602, the input/output interface 603, and the communication interface 604 are interconnected within the device via the bus 605 to achieve communication.

The embodiments of this application also provide a computer-readable storage medium, which is a non-transitory computer-readable storage medium storing computer programs. When executed by a processor, these computer programs implement the aforementioned read-write testing method for memory storage devices.

As a non-transitory computer-readable storage medium, the memory can be used to store non-transitory software programs and non-transitory computer-executable programs. Additionally, the memory may comprise high-speed random-access memory and may also comprise non-transitory memory, such as at least one disk storage device, flash memory device, or other non-transitory solid-state storage devices. In some implementations, the memory may optionally comprise memory located remotely from the processor, and these remote memories can be connected to the processor via a network. Examples of such networks comprise, but are not limited to, the Internet, intranets, local area networks, mobile communication networks, and combinations thereof.

The embodiments described in this application are intended to provide a clearer explanation of the technical solutions of the embodiments of this application and do not constitute limitations on the technical solutions provided by the embodiments of this application. Those skilled in the art will appreciate that with the evolution of technology and the emergence of new application scenarios, the technical solutions provided by the embodiments of this application are equally applicable to similar technical problems.

Those skilled in the art can understand that the technical solutions depicted in the figures do not constitute limitations on the embodiments of this application. They may comprise more or fewer steps than those shown, combine certain steps, or have different steps.

The device embodiments described above are merely illustrative. The units described as separate components may or may not be physically separated, meaning they can be located in one place or distributed across multiple network units. Depending on actual needs, some or all of the modules can be selected to achieve the objectives of the embodiments of this application.

Those of ordinary skill in the art can understand that all or some of the steps in the methods disclosed above, as well as the functional modules/units in systems and devices, can be implemented as software, firmware, hardware, or a suitable combination thereof.

The terms "first," "second," "third," "fourth," etc. (if present) in the description and the accompanying figures of this application are used to distinguish similar objects and do not necessarily indicate a specific order or sequence. It should be understood that the data used in this way can be interchanged as appropriate, so that the embodiments of this application described herein can be implemented in orders other than those illustrated or described herein. Furthermore, the terms "comprise" and "have," as well as any variations thereof, are intended to cover non-exclusive inclusions. For example, a process, method, system, product, or device that comprises a series of steps or units is not necessarily limited to those clearly listed steps or units but may comprise other steps or units that are not clearly listed or inherent to such processes, methods, products, or devices.

It should be understood that in this application, "at least one (item)" refers to one or more, and "multiple" refers to two or more. The term "and/or" is used to describe the relationship between associated objects and indicates that three relationships may exist, for example, "A and/or B" can mean: only A exists, only B exists, and both A and B exist simultaneously, where A and B can be singular or plural. The character "/" generally indicates that the associated objects before and after it have an "or" relationship. "At least one (item)" or similar expressions refer to any combination of these items, including single or multiple items. For example, "at least one (item) of a, b, or c" can mean a, b, c, "a and b," "a and c," "b and c," or "a and b and c," where a, b, and c can be singular or plural.

In the several embodiments provided by this application, it should be understood that the disclosed devices and methods can be implemented in other ways. For example, the device embodiments described above are merely illustrative. For example, the division of the aforementioned units is merely a logical functional division, and in actual implementations, there may be other division methods, such as multiple units or components being combined or integrated into another system, or some features being ignored or not executed. Additionally, the coupling or direct coupling or communication connection shown or discussed between each other can be indirect coupling or communication connection through some interfaces, devices, or units, and can be electrical, mechanical, or other forms.

The units described as separate components may or may not be physically separated, and the components displayed as units may or may not be physical units, meaning they can be located in one place or distributed across multiple network units. Depending on actual needs, some or all of the units can be selected to achieve the objectives of the embodiments of this application.

Furthermore, in various embodiments of this application, the functional units can be integrated into one processing unit, or each unit can exist physically separately, or two or more units can be integrated into one unit. The aforementioned integrated units can be implemented in hardware or as software functional units.

If the integrated unit is implemented as a software functional unit and sold or used as an independent product, it can be stored in a computer-readable storage medium. Based on this understanding, the technical solutions of this application, or the parts that contribute to the existing technology, or all or part of the technical solutions, can be embodied in the form of a software product. This computer software product is stored in a storage medium and comprises multiple instructions for enabling a computer device (which can be a personal computer, server, or network device, etc.) to execute all or part of the steps of the methods in various embodiments of this application. The aforementioned storage medium comprises various media that can store programs, such as USB flash drives, mobile hard drives, read-only memory (ROM), random-access memory (RAM), magnetic disks, or optical disks.

The above descriptions of the preferred embodiments of this application with reference to the accompanying figures are not intended to limit the scope of the rights of the embodiments of this application. Any modifications, equivalent substitutions, and improvements made within the scope and spirit of the embodiments of this application by those skilled in the art should fall within the scope of the rights of the embodiments of this application.

1. A read-write testing method for a memory storage device, comprising:
obtaining a number of data blocks of a target memory storage device to be tested and a number of rows in each of the data blocks;
determining a number of test threads to be created based on the number of data blocks, the number of rows, and the read-write type;
creating the number of test threads and determining read-write starting positions for each of the test threads from row regions of each of the data blocks;
synchronously invoking each of created test threads and outputting the test results, so as to perform synchronous read-write testing from corresponding read-write starting positions through each of the test threads;
wherein the test threads comprise read threads, write threads, and comparison threads; the read threads, the write threads, and the comparison threads are provided in a one-to-one correspondence; wherein multiple read-write types are provided, and the multiple read-write types comprise block-by-block read-write and multi-block read-write; the determining the number of test threads to be created based on the number of data blocks, the number of rows, and the read-write type, comprises:
determining a first number of threads corresponding to block-by-block read-write based on the number of rows, wherein each test thread corresponds to the row region of at least one row;
obtaining the maximum number of write threads that are created; the maximum number of writable threads is one-third of the supported maximum number of threads;
dividing the maximum number of write threads by the number of data blocks and rounding down the result to determine the first thread multiple when the maximum number of write threads is greater than or equal to the number of data blocks;
determining the number of data block write threads for a single data block based on the first thread multiple;
determining the target number of write threads based on the number of data block write threads and the number of data blocks;
determining the second number of threads corresponding to multi-block read-write based on the target number of write threads;
determining a number of threads based on the first number of threads and the second number of threads.
wherein the synchronously invoking each of the created test threads and outputting the test results, comprises:
invoking each of the write threads to perform write operations from the corresponding read-write starting positions;
invoking each of the read threads to perform read operations from the read-write starting positions after the data at each of the read-write starting positions has been written;
invoking the comparison threads to compare the operation data of the corresponding write threads and read threads and output the comparison results.

2. The read-write testing method for the memory storage device according to claim 1, wherein the method further comprises:
dividing the number of data blocks by the maximum number of write threads and rounding up the result to determine the second thread multiple when the maximum number of write threads is less than the number of data blocks;
determining the second number of threads corresponding to multi-block read-write based on the second thread multiple.

3. The read-write testing method for the memory storage device according to claim 1, wherein the determining the read-write starting positions for each of the test threads from the row regions of each of the data blocks, comprises:
obtaining the second thread mapping relationship corresponding to the second number of threads under multi-block read-write;
determining the starting data blocks for each of the test threads under multi-block read-write based on the second thread mapping relationship;
randomly generating the second starting row numbers for each of the starting data blocks;
randomly generating a read-write starting position from the corresponding row region for each of the second starting row numbers.

4. The read-write testing method for the memory storage device according to claim 1, wherein the determining the first number of threads corresponding to block-by-block read-write based on the number of rows, comprises:
obtaining the maximum number of write threads that are created;
dividing the number of rows by the maximum number of write threads and rounding up the result to determine the third thread multiple;
determining the first number of threads corresponding to block-by-block read-write based on the third thread multiple.

5. The read-write testing method for the memory storage device according to claim 4, wherein the determining the read-write starting positions for each of the test threads from the row regions of each of the data blocks, comprises:
identifying target data blocks from each of the data blocks;
obtaining the first thread mapping relationship corresponding to the first number of threads;
determining the second starting row numbers for each test thread corresponding to block-by-block read-write in the target data blocks based on the first thread mapping relationship;
randomly generating the read-write starting positions in the row regions corresponding to the second starting row numbers for each of the test threads.

6. An electronic device, wherein the electronic device comprises a memory and a processor, the memory stores a computer program, and the processor, when executing the computer program, implements the read-write testing method for a memory storage device according to claim 1.

7. A computer-readable storage medium, the storage medium stores a computer program, wherein the computer program, when executed by a processor, implements the read-write testing method for a memory storage device according to claim 1.
